(19) United States
(12) Patent Application Publication
(10) Pub. No.: US 2026/0322374 A1
(43) Pub. Date: Oct. 15, 2026

(54) SYSTEM AND METHOD FOR REDUCING MILLER EFFECT AND CROSSTALK IN SILICON CARBIDE MOSFETS VIA INJECTION OF NONLINEAR CURRENT

(71) Applicant: University of Florida Research Foundation, Incorporated, Gainesville, FL (US)

(72) Inventors: Shuo Wang, Gainesville, FL (US); Yirui Yang, Gainesville, FL (US); Zhijie Zhang, Gainesville, FL (US); Daniel D. Smith, Gainesville, FL (US)

(21) Appl. No.: 19/560,790

(22) Filed: Mar. 9, 2026

Related U.S. Application Data
(60) Provisional application No. 63/789,170, filed on Apr. 15, 2025.

(51) Int. Cl. H03K 17/16

(52) U.S. Cl. CPC H03K 17/165

(57) ABSTRACT

A system comprising a current injection network that is coupled to a main circuit. The main circuit comprises a metal-oxide-semiconductor field-effect transistor (MOSFET), wherein the current injection network (i) is configured to provide a cancelation current to the MOSFET and (ii) comprises a gain stage subcircuit that is configured to (a) scale a drain-to-source voltage of the MOSFET, (b) provide an injection capacitor comprising a nonlinearity that matches a magnitude of a gate-to-drain capacitance current of the MOSFET, and (c) generate the cancelation current via the injection capacitor; and an inversion stage subcircuit that is configured to invert a scaled drain-to-source voltage that is received from the gain stage subcircuit.

### CROSS REFERENCE TO RELATED APPLICATION

This application claims the priority of U.S. Provisional Application No. 63/789,170, entitled “SYSTEM AND METHOD FOR REDUCING MILLER EFFECT AND CROSSTALK IN SILICON CARBIDE MOSFETS VIA INJECTION OF NONLINEAR CURRENT,” filed on Apr. 15, 2025, the disclosure of which is hereby incorporated by reference in its entirety.

### GOVERNMENT SUPPORT

This invention was made with government support under Grant No. DE-AR0001914, awarded by the U.S. Department of Energy. The government has certain rights in the invention.

### TECHNICAL FIELD

Various embodiments of the present disclosure relate to improving the performance and reliability of silicon carbide (SiC) metal-oxide-semiconductor field-effect transistors (MOSFETs), and more particularly to mitigating the impact of Miller capacitance on SiC MOSFETs.

### BACKGROUND

Silicon carbide (SiC) metal-oxide-semiconductor field-effect transistors (MOSFETs) may have multiple advantages in high power switching applications over traditional silicon devices of similar power ratings. Despite this, SiC MOSFETs are not being fully utilized in the industry due to some significant barriers, such as electromagnetic interference (EMI) and Miller capacitance/effect. Miller capacitance, or drain-to-gate capacitance, of a SiC MOSFET may cause undesirable effects during switching, known as the Miller effect. For example, when two SiC MOSFETs are complementary in a phase-leg configuration, a resulting Miller capacitance at high frequency/voltage switching may lead to a Miller plateau and crosstalk between the MOSFETs thereby reducing switching speed and reliability. Applicant has identified many technical challenges and difficulties associated with SiC MOSFETs.

### BRIEF SUMMARY

Various embodiments described herein relate to methods, apparatus, systems, and/or the like for improving the performance and reliability of metal-oxide-semiconductor field-effect transistors (MOSFETs).

According to some embodiments, a system comprises a current injection network that is coupled to a main circuit, the main circuit comprising a metal-oxide-semiconductor field-effect transistor (MOSFET), wherein the current injection network (i) is configured to provide a cancelation current to the MOSFET and (ii) comprises a gain stage subcircuit that is configured to (a) scale a drain-to-source voltage of the MOSFET, (b) provide an injection capacitor comprising a nonlinearity that matches a magnitude of a gate-to-drain capacitance current of the MOSFET, and (c) generate the cancelation current via the injection capacitor; and an inversion stage subcircuit that is configured to invert a scaled drain-to-source voltage that is received from the gain stage subcircuit.

In some embodiments, the gain stage subcircuit comprises a nonlinear capacitance voltage divider circuit that includes a first gain stage diode, a second gain stage diode, a gain stage resistor, a first gain stage capacitor, and a second gain stage capacitor. In some embodiments, the first gain stage diode and the second gain stage diode are reversely biased during a normal mode of operation. In some embodiments, the second gain stage capacitor comprises an impedance that is significantly smaller than an impedance of the first gain stage capacitor and an impedance of a junction capacitance associated with the first gain stage diode. In some embodiments, the gain stage resistor (i) comprises a resistance value that is significantly larger than the impedance of the second gain stage capacitor and (ii) is configured in parallel with the second gain stage capacitor to discharge the second gain stage capacitor upon disconnecting the gain stage subcircuit from the main circuit.

In some embodiments, the second gain stage diode is configured to clamp a negative output voltage. In some embodiments, the second gain stage diode comprises a junction capacitance corresponding to an impedance that is significantly larger than an impedance of the second gain stage capacitor. In some embodiments, the first gain stage diode comprises a reversely biased high voltage diode with a nonlinear junction capacitance that is voltage dependent and nonlinear. In some embodiments, a voltage across the first gain stage diode and the first gain stage capacitor is approximately equal to the drain-to-source voltage. In some embodiments, the inversion stage subcircuit comprises an N-MOSFET that is configured to an output of the gain stage subcircuit. In some embodiments, the inversion stage subcircuit comprises an output that is coupled to the injection capacitor.

According to some embodiments, a system comprises a nonlinear voltage sensing network that is coupled to a metal-oxide-semiconductor field-effect transistor (MOSFET), wherein the nonlinear voltage sensing network is configured to generate an injection voltage; an inverting linear amplifier that is configured to generate an inverted injection voltage from the injection voltage; and an injection capacitor that is coupled to the inverting linear amplifier, wherein the injection capacitor is configured to provide a cancelation current to the MOSFET from the inverted injection voltage.

### BRIEF DESCRIPTION OF THE DRAWINGS

Embodiments incorporating teachings of the present disclosure are shown and described with respect to the figures presented herein.

FIG. 1 depicts a schematic diagram of an example metal-oxide-semiconductor field-effect transistors (MOSFET) circuit.

FIG. 2 depicts a waveform of example gate voltages of two complementary MOSFETs with respect to the drain-to-source voltage.

FIG. 3 depicts a schematic diagram of an example silicon carbide (SiC) MOSFET circuit in accordance with some embodiments of the present disclosure.

FIG. 4 depicts a schematic diagram of an example gain stage subcircuit in accordance with some embodiments of the present disclosure.

FIG. 5 depicts a schematic diagram of an example inversion stage subcircuit in accordance with some embodiments of the present disclosure.

FIG. 6 depicts a schematic diagram of an example nonlinear injection network in accordance with some embodiments of the present disclosure.

FIG. 7 depicts a schematic diagram of an example nonlinear voltage sensing network of a nonlinear injection network in accordance with some embodiments of the present disclosure.

FIG. 8 depicts an example reduction of a nonlinear voltage sensing network in accordance with some embodiments of the present disclosure.

FIG. 9 depicts a schematic diagram of an example inverting linear amplifier of a nonlinear injection network in accordance with some embodiments of the present disclosure.

FIG. 10 depicts a schematic diagram of an example injection network circuit in accordance with some embodiments of the present disclosure.

### DETAILED DESCRIPTION

Various embodiments of the present disclosure now will be described more fully hereinafter with reference to the accompanying drawings, in which some, but not all embodiments of the disclosure are shown. Indeed, the disclosure may be embodied in many different forms and should not be construed as limited to the embodiments set forth herein. Rather, these embodiments are provided so that this disclosure will satisfy applicable legal requirements. The term “or” is used herein in both the alternative and conjunctive sense, unless otherwise indicated. The terms “illustrative,” “example,” and “exemplary” are used to be examples with no indication of quality level. Like numbers refer to like elements throughout.

### General Overview and Example Technical Improvements

The present disclosure provides a technique for mitigating adverse effects of Miller capacitance in silicon carbide (SiC) metal-oxide-semiconductor field-effect transistors (MOSFETs) by implementing a nonlinear current injection network. Various embodiments of the present disclosure effectively reduce both the Miller plateau and crosstalk, leading to significant improvements in switching performance, thereby enhancing overall power efficiency and device reliability.

Switching performance of a MOSFET may be affected by the Miller effect when the MOSFET's gate voltage is temporarily “clamped” or held around the threshold voltage, which may delay the turn-on and turn-off process of the MOSFET, and in turn, increase switching time (e.g., rising and falling times of the affected MOSFET's drain-to-source voltage). Such a delay, also known as the Miller plateau, may be undesirable as it increases switching power loss and decreases power efficiency. A Miller plateau may occur due to an interaction between the power loop and drive loop of a MOSFET configuration and forces a significant amount of Miller current to flow through a Miller capacitor.

Accordingly, the reliability of a MOSFET may be compromised by the Miller effect when the MOSFET's gate voltage experiences a significant voltage spike during a switching transient. The gate voltage may experience a positive or negative voltage spike as the MOSFET's drain-to-source voltage increases or decreases. Such induced voltage spikes, also known as the crosstalk effect, occur due to Miller current flow through the Miller capacitance. The induced voltage spikes not only reduce MOSFET reliability but may also reduce system reliability. A positive spike may introduce a false triggering as it may potentially raise the gate voltage of the MOSFET beyond the threshold voltage. As such, it may be desirable to avoid false triggering as it increases switching loss and may also short the circuit, damaging all components. Whereas a negative spike may introduce a voltage induced gate oxide breakdown that may potentially damage the MOSFET. A negative spike may occur when a large enough negative voltage is applied to the gate and the thin insulating layer (gate oxide) becomes conductive, allowing significant current flow.

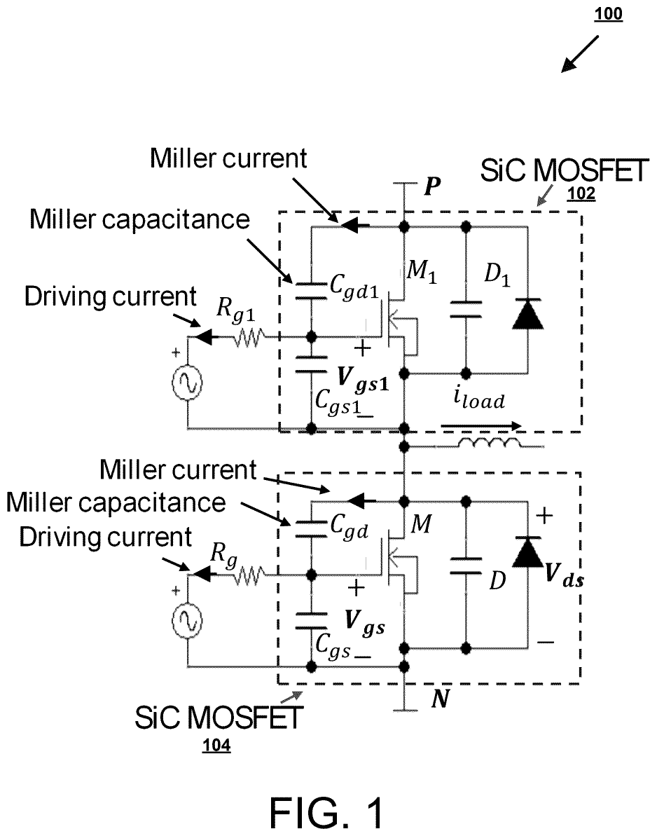

FIG. 1 depicts a schematic diagram of an example MOSFET circuit 100. The MOSFET circuit 100 comprises two MOSFETs 102 and 104 in a phase-leg configuration. When the two MOSFETs 102 and 104 are connected in a phase-leg configuration, both the Miller plateau and crosstalk may occur. However, only one of Miller plateau or crosstalk may occur in a single MOSFET. As such, gate voltage of one MOSFET (e.g., 102) may experience the Miller plateau while the other MOSFET's (e.g., 104) gate voltage may experience crosstalk.

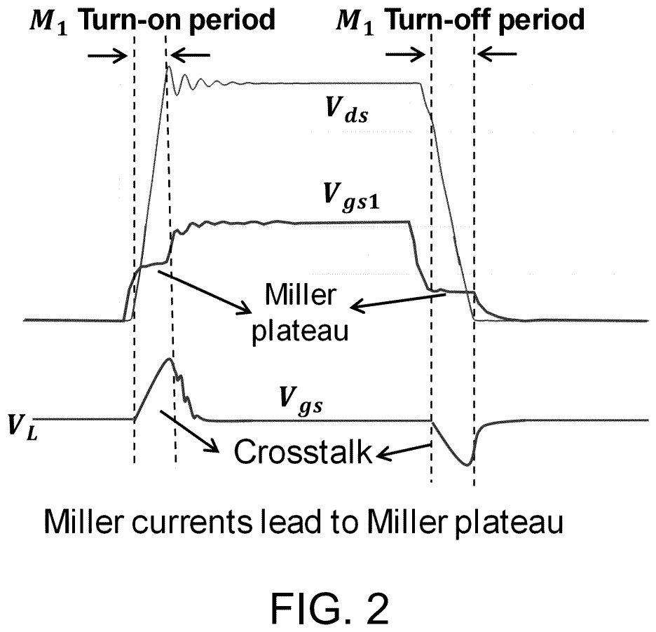

FIG. 2 depicts a waveform of example gate voltages of two complementary MOSFETs with respect to the drain-to-source voltage. Both Miller plateau and crosstalk are depicted by comparing the gate voltages of two complementary MOSFETs (V_{gs} and V_{gs1}) with respect to drain-to-source voltage (V_{ds}). In this case, V_{gs} experiences crosstalk and V_{gs1} experiences the Miller plateau.

Given that Miller current may comprise a primary cause of the Miller effect, reducing, eliminating, and/or negating the Miller current may effectively mitigate its impact. According to various embodiments of the present disclosure, a cancellation current is injected into a gate of a SiC MOSFET via an injection network. In some embodiments, the injection network is configured to inject a true nonlinear current for Miller capacitance cancellation. Thus, the closer an injection current is to the Miller current, the more effective the cancellation may be.

### Example Nonlinear Current Injection Networks

### Gain and Inversion Injection Network Design

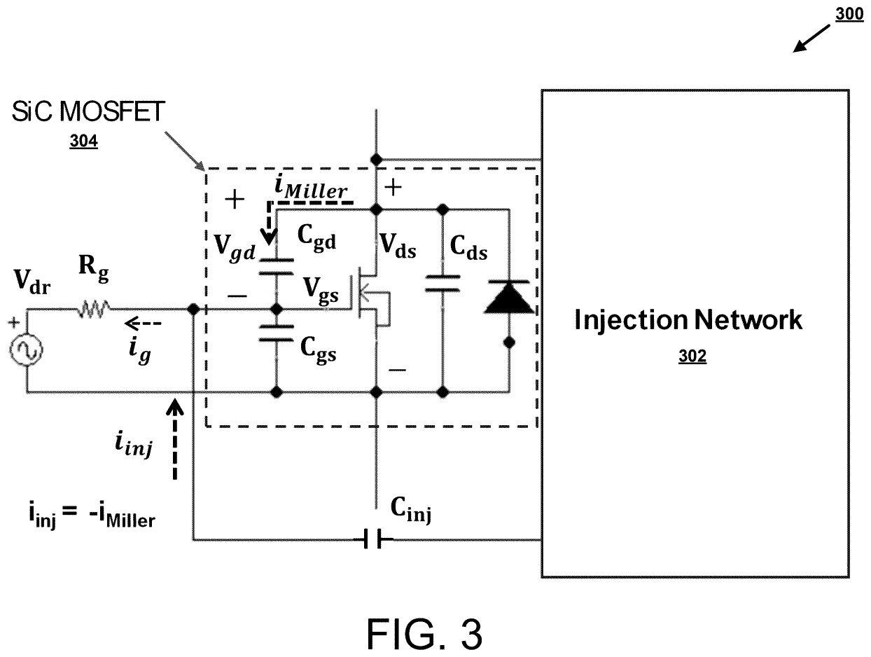

FIG. 3 depicts a schematic diagram of an example SiC MOSFET circuit 300 in accordance with some embodiments of the present disclosure. The SiC MOSFET circuit 300 comprises an injection network 302 for Miller capacitance cancelation. The injection network 302 may comprise circuitry that is configured to inject a cancellation current to the gate of the SiC MOSFET 304 (e.g., MOSFET 102 or 104 of FIG. 1) to cancel Miller current i_{Miller}, thereby reducing, canceling, and/or eliminating the Miller effect.

In some embodiments, the injection network 302 comprises two stages: a gain stage and an inversion stage. Gate-to-drain capacitance C_{gd}, drain-to-source capacitance C_{ds}, and gate-to-source capacitance C_{gs} may comprise junction capacitance inside the SiC MOSFET 304. The gain stage may be configured to scale V_{ds} and introduce a desired nonlinearity to effectively match the magnitude of a current flowing through gate-to-drain capacitance C_{gd}. The inversion stage may be configured to invert a scaled voltage (from the gain stage) to ensure that a cancelation current is opposite to the current flowing through C_{gd}. The cancelation current may be injected via an injection capacitor Cᵢₙⱼ.

The Miller capacitance associated with C_{gd} may be represented as a function of V_{ds} as given by Equation 1, where V₀, C₀, and n may be constants.

$${C}_{gd} ( {V}_{gd} ) = \frac{{C}_{0}}{{( 1 + \frac{{V}_{gd}}{{V}_{0}} )}^{n}} \approx \frac{{C}_{0}}{{( 1 + \frac{{V}_{ds}}{{V}_{0}} )}^{n}} = {C}_{gd} ( {V}_{ds} ) , ( Since {V}_{ds} ≫ {V}_{gs} ) \qquad \underline{Equation 1}$$

The total gain Gᵢₙⱼ of the injection network 302 may be obtained by:

$${G}_{inj} ( {V}_{ds} ) = \frac{{V}_{inj}}{{V}_{ds}} = {G}_{G} ( {V}_{ds} ) {G}_{inv} = - \frac{{C}_{gd} ( {V}_{gd} )}{{C}_{inj}} \qquad \underline{Equation 2}$$

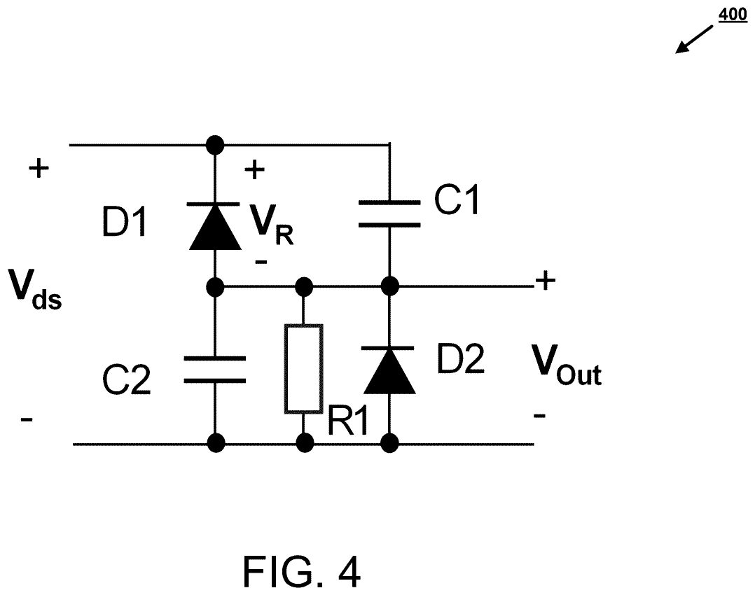

The objective of the gain stage may comprise scaling down V_{ds} and introducing a desired nonlinearity into the network while avoiding significant introduction of extra capacitance to drain-to-source capacitance C_{ds}. Since the junction capacitance associated with C_{gd} of the SiC MOSFET 304 is nonlinear, the nonlinearity of the injection network 302 may be realized by using a nonlinear junction capacitance of a semiconductor device, as depicted in FIG. 4.

FIG. 4 depicts a schematic diagram of an example gain stage subcircuit 400 in accordance with some embodiments of the present disclosure. The gain stage subcircuit 400 comprises a nonlinear capacitance voltage divider. In normal operating status, diodes D1 and D2 are reversed biased. Capacitor C2 may comprise an impedance that is significantly smaller than the impedance of capacitor C1 (capacitance bias) and the junction capacitance of D1. Furthermore, resistor R1 and D2 may be configured for protection purposes. R1 may comprise a resistance value that is significantly larger than the impedance of C2 and is configured in parallel with C2 to discharge C2 when the gain stage subcircuit 400 is disconnected from the main circuit. D2 may clamp the negative output voltage (e.g., reverse voltage protection). The junction capacitance of D2 may be small such that its impedance is significantly larger than that of C2. As such, R1 and D2 may be negligible or ignored in gain calculation. D1 may comprise a reversely biased high voltage diode with a nonlinear junction capacitance that is voltage dependent, nonlinear, and follows the Equation 1. C1 may serve as a base capacitance for the top leg as it is not voltage dependent.

The V_{ds} of a SiC MOSFET (e.g., MOSFET 104 of FIG. 1) may comprise hundreds of volts while the output voltage Vₒᵤₜ of the gain stage subcircuit 400 may comprise a few volts. As such, the voltage across D1 and C1 may be estimated to be roughly equal to V_{ds}, which may simplify gain calculation and allow for efficient matching of a desired C_{gd} curve. Equation 3 may provide a nonlinear gain G_{G} for the gain stage,

$${G}_{G} ( {V}_{ds} ) = \frac{{V}_{Out}}{{V}_{ds}} \approx \frac{{C}_{1}}{{C}_{2}} + \frac{{C}_{0}^{′} / {C}_{2}}{{( 1 + \frac{{V}_{ds}}{{V}_{0}^{′}} )}^{m}} \qquad \underline{Equation 3}$$

The gain of the inversion stage Gᵢₙᵥ may be given by,

Gᵢₙⱼ(V_{ds})=G_{G}(V_{ds})·Gᵢₙᵥ Equation 4

From Equations 1 through 4, C1, C2, and the junction capacitance of D1 may be determined using curve fitting. If the inversion stage comprises a gain Gᵢₙᵥ=−1, the injection network gain Gᵢₙⱼ may be −G_{G}. Cᵢₙⱼ may comprise a scalar to scale the gain closer to meet Equation 2. After a plurality of iterations, a finalized curve of equivalent C_{gd}′=−G_{G}GᵢₙᵥCᵢₙⱼ, when Gᵢₙᵥ=−1, compared with that of the C_{gd} of the SiC MOSFET may be determined.

A value of C_{gd}′ may be obtained that is approximately equal or substantially similar to the actual C_{gd} of the SiC MOSFET, which may correspond to an approximate or substantially near satisfaction of Equation 2. For example, a SiC MOSFET may comprise a SCT3060AR with 650V/39A rating and may comprise a gain stage subcircuit with values of C1=1 pF, C2=3 nF, and R1=60 MΩ, where values for V₀′, C₀′, and m may be derived based on a high voltage diode, such as RFUH20TJ6S. The Cᵢₙⱼ may comprise a value of 5 nF but may be modified as needed. For example, if the inversion stage provides a gain other than −1 (ideal), Cᵢₙⱼ may be used as a scalar to compensate.

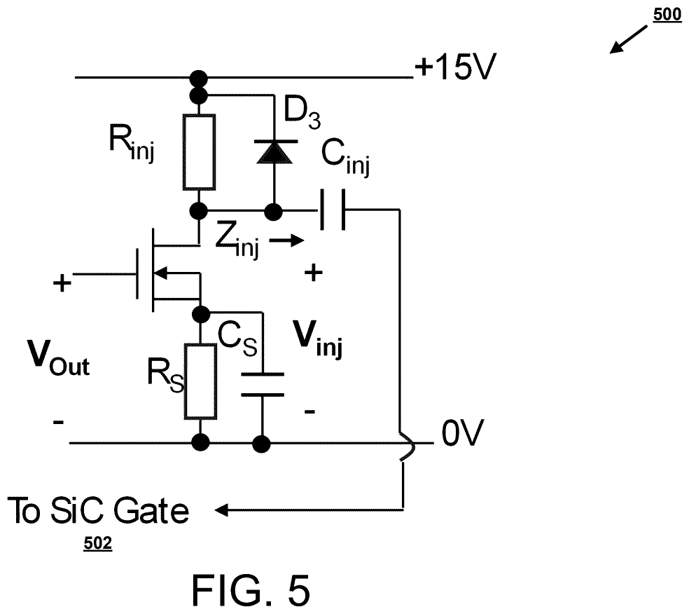

FIG. 5 depicts a schematic diagram of an example inversion stage subcircuit 500 in accordance with some embodiments of the present disclosure. The inversion stage subcircuit 500 may comprise an inverting circuit. The output of a gain stage subcircuit (e.g., gain stage subcircuit 400) may be directly fed into the gate 502 of a SiC N-MOSFET. An external 15V voltage source is used to power the inversion stage subcircuit 500. The output of the inversion stage subcircuit 500 connects directly to the injection capacitor Cᵢₙⱼ which may remove DC bias and deliver a nonlinear AC current. The emitter resistance R_{S} may be used to establish a DC operating point and prevent thermal runaway.

A parallel capacitor C_{S} may bypass R_{S} and achieve a substantial gain at high frequencies. If R_{g} is a resistor in the gate driving loop of the SiC N-MOSFET, at frequencies where the impedance of C_{S} is significantly less than that of R_{S}, the gain Gᵢₙᵥ may be determined by:

$$\{ \begin{matrix}{G}_{inv} = \frac{{V}_{inj}}{{V}_{out}} = - {g}_{m} {Z}_{inj} // {R}_{inj} \\ {Z}_{inj} = \frac{1}{j ω {C}_{inj}} + {R}_{g} // [ \frac{1}{j ω ( {C}_{gs} + {C}_{gd} )} ]\end{matrix} \qquad \underline{Equation 5}$$

In Equation 5, the transconductance gₘ may comprise a known value that is provided for the SiC N-MOSFET (e.g., A06608). In some embodiments, an ideal gain of −1 may be desired from the inversion stage subcircuit 500. Based on Equation 5, a larger Rᵢₙⱼ may lead to a higher Gᵢₙᵥ in a certain frequency range, however, Rᵢₙⱼ may also be directly related to a maximum current injected to the gate 502 for cancellation. Accordingly, Gᵢₙᵥ may be limited by the maximum injection current and vice versa. Therefore, the gain may be adjusted to accommodate for a sufficient injection current instead of a desired gain of −1. The total injection network gain may be corrected by adjusting Cᵢₙⱼ as needed.

For example, an inversion stage subcircuit 500 may comprise R_{g} configured to 15Ω, Rᵢₙⱼ configured to 8.2Ω, R_{S} configured to 6.9Ω, C_{S} configured to a 10 nF, and diode D3 configured as a 1N914 diode. A corner frequency determined by R_{S} and C_{S} may be 2.3 MHz, which corresponds to the inversion stage subcircuit 500 comprising a gain according to Equation 5 for signals with frequencies higher than 2.3 MHz, otherwise, the gain may be significantly smaller for signals at frequencies below 2.3 MHz. D3 may be configured to protect the SiC N-MOSFET if there are reverse currents flowing from the gate 502 of the SiC MOSFET.

### Nonlinear Injection Network Design

In some embodiments, the Miller capacitance associated with C_{gd} may be represented as a non-linear function of V_{gd} as given by Equation 6,

$${C}_{gd} ( {V}_{gd} ) = \frac{{C}_{0}}{{( 1 + \frac{{V}_{gd}}{{V}_{0}} )}^{n}} \qquad \underline{Equation 6}$$

The non-linear function is incompatible with a conventional linear amplifier-based network, and as such, a nonlinear injection network may be designed with a specific gain curve.

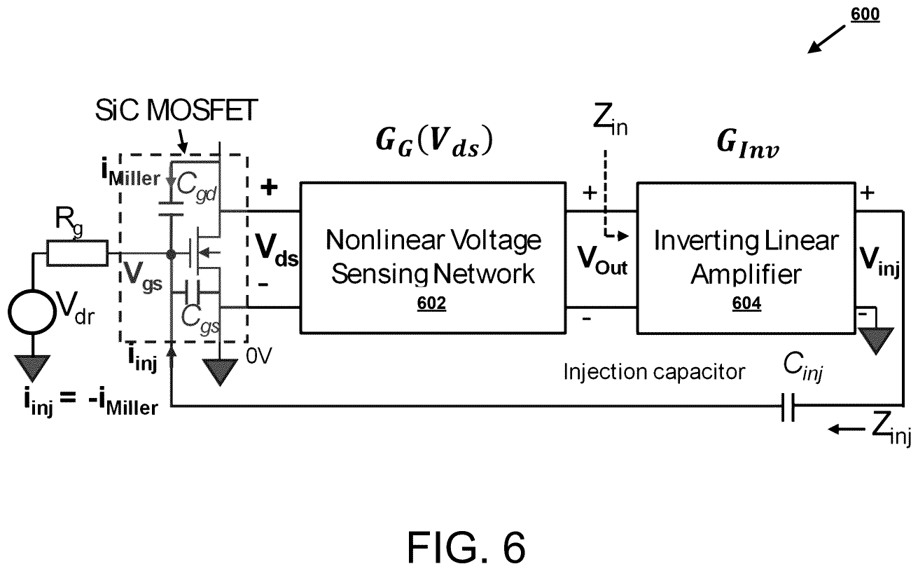

FIG. 6 depicts a schematic diagram of an example nonlinear injection network 600 in accordance with some embodiments of the present disclosure. The nonlinear injection network 600 comprises a nonlinear voltage sensing network 602 and an inverting linear amplifier 604. The nonlinear voltage sensing network 602 may be obtained by determining a (Miller effect) cancelation condition based on,

$${C}_{inj} = - \frac{{C}_{gd}}{{G}_{G} ( {V}_{ds} {G}_{Inv} )} \qquad \underline{Equation 7}$$

where,

G_{G}(V_{ds})=Vₒᵤₜ/V_{ds} Equation 8

Gᵢₙᵥ=Vᵢₙⱼ/Vₒᵤₜ Equation 9

may be used to obtain,

Vᵢₙⱼ=V_{ds}·G_{G}(V_{ds})·G_{Inv} Equation 10

and

iᵢₙⱼ=(Vᵢₙⱼ−V_{gs})jωCᵢₙⱼ Equation 11

i_{Miller}=(V_{ds}−V_{gs})jωC_{gd} Equation 12

iᵢₙⱼ=−i_{Miller} Equation 13

may be used to obtain,

$$\frac{{C}_{inj}}{{C}_{gd}} = - \frac{{V}_{ds}}{{V}_{inj}} \qquad \underline{Equation 14}$$

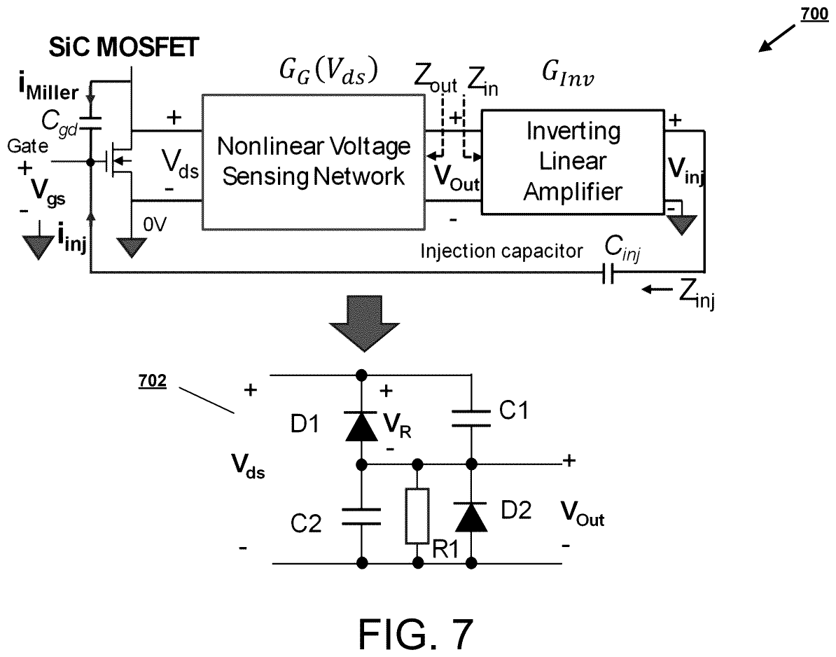

FIG. 7 depicts an example derivation of a nonlinear voltage sensing network 702 for a nonlinear injection network 700 in accordance with some embodiments of the present disclosure. Using Equation 10 and where

iᵢₙⱼ=Vᵢₙⱼ/Zᵢₙⱼ, Equation 15

a nonlinear voltage sensing network 702 may be obtained.

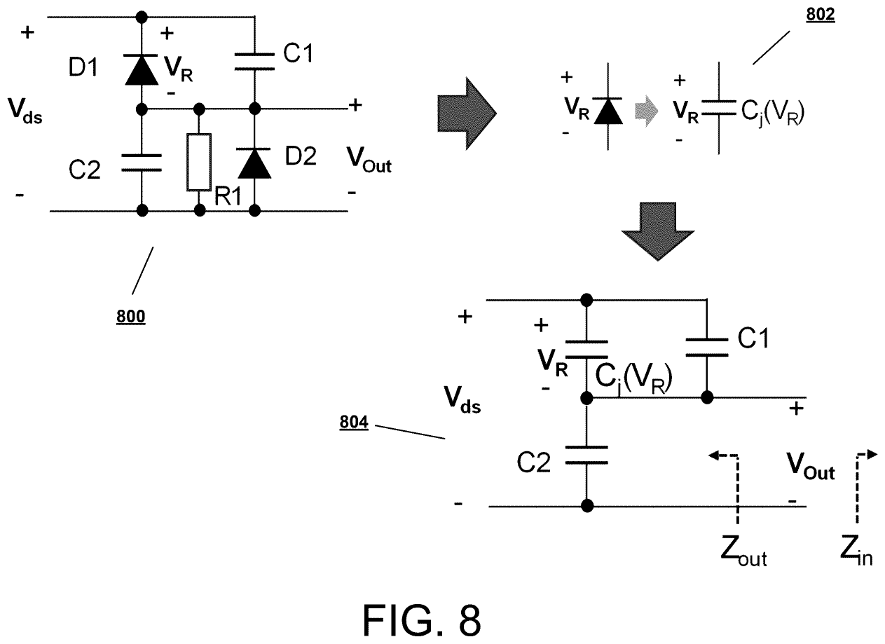

FIG. 8 depicts an example reduction of a nonlinear voltage sensing network 800 in accordance with some embodiments of the present disclosure. A reduced nonlinear voltage sensing network 804 is obtained based on the nonlinear voltage sensing network 800 by substituting D1 with Cⱼ(V_{R}) 802, where

$${C}_{j} ( {V}_{R} ) = \frac{{c}_{0}^{′}}{{( 1 + \frac{{V}_{R}}{{V}_{0}^{′}} )}^{m}} , \qquad \underline{Equation 16}$$

Z_{R1}//Z_{D2}>>Z_{C1//Cj}>>Z_{C2}, and V_{ds}>>Vₒᵤₜ.

Based on the reduced nonlinear voltage sensing network 804, a gain of the nonlinear voltage sensing network may be obtained based on Equation 16 and if Zₒᵤₜ<<Zᵢₙ,

$${G}_{G} ( {V}_{ds} ) = \frac{{V}_{Out}}{{V}_{ds}} = \frac{{C}_{1} + \frac{{C}_{0}^{′}}{{( 1 + \frac{{V}_{R}}{{V}_{0}^{′}} )}^{m}}}{{C}_{1} + {C}_{2} + \frac{{C}_{0}^{′}}{{( 1 + \frac{{V}_{R}}{{V}_{0}^{′}} )}^{m}}} . \qquad \underline{Equation 17}$$

Given C2>>C1, Cⱼ, then,

$${G}_{G} ( {V}_{ds} ) = \frac{{V}_{Out}}{{V}_{ds}} \approx \frac{{C}_{1}}{{C}_{2}} + \frac{{C}_{0}^{′} / {C}_{2}}{{( 1 + \frac{{V}_{ds}}{{V}_{0}^{′}} )}^{m}} . \qquad \underline{Equation 18}$$

Values for C1, C2, Cᵢₙⱼ, and D1 may be determined such that,

$$- {G}_{G} ( {V}_{ds} ) \cdot {G}_{Inv} \cdot {C}_{Inj} \approx {C}_{gd} ( {V}_{ds} ) = \frac{{C}_{0}}{{( 1 + \frac{{V}_{ds}}{{V}_{0}} )}^{n}} \qquad \underline{Equation 19}$$

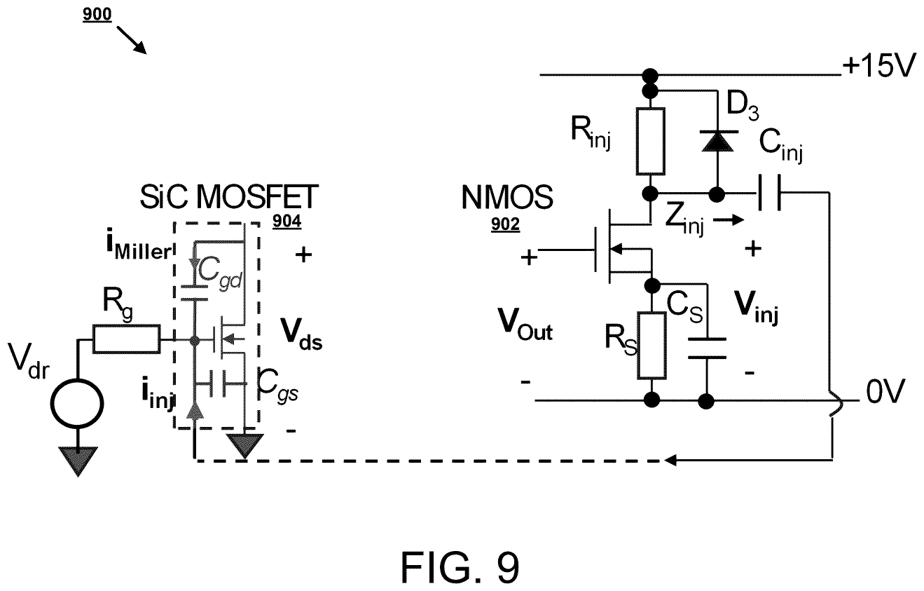

FIG. 9 depicts a schematic diagram of an example inverting linear amplifier 900 of a nonlinear injection network in accordance with some embodiments of the present disclosure. The inverting linear amplifier 900 may be obtained by determining the gain Gᵢₙᵥ, where

$${G}_{inv} = \frac{{V}_{inj}}{{V}_{out}} = - {g}_{m} {Z}_{inj} // {R}_{inj} , \qquad \underline{Equation 20}$$

where

$${Z}_{inj} = \frac{1}{j ω {C}_{inj}} + {R}_{g} // [ \frac{1}{j ω ( {C}_{gs} + {C}_{gd} )} ] \qquad \underline{Equation 19}$$

R_{S} may be used to establish a DC operating point and prevent thermal run-away. C_{S} may help signal to bypass R_{S}, thereby achieving a high gain at high frequencies. D₃ may be used to protect the NMOS 902 from reverse current/voltage damage from the SiC MOSFET 904 gate.

### Example Injection Network Circuit

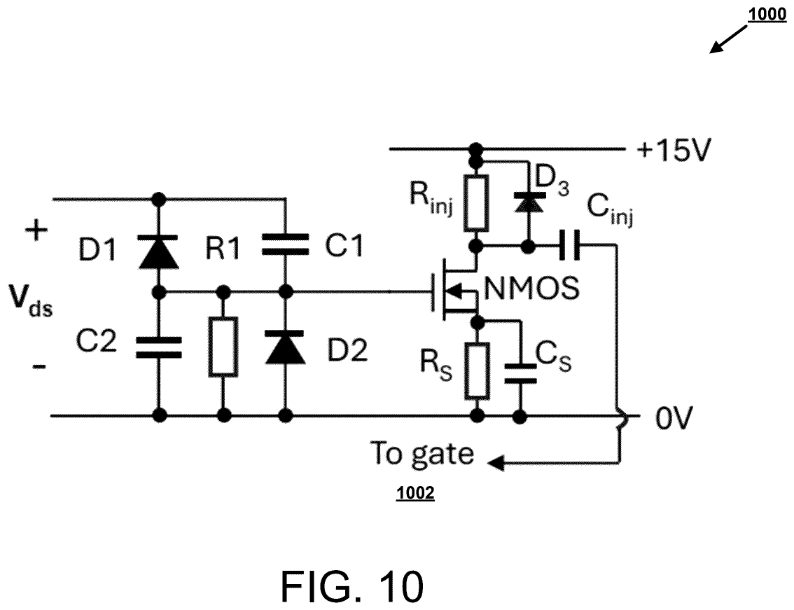

FIG. 10 depicts a schematic diagram of an example injection network circuit 1000 in accordance with some embodiments of the present disclosure. According to various embodiments of the present disclosure, an injection network circuit 1000, obtained by either the gain and inversion injection network design or the nonlinear injection network design, is coupled to a MOSFET gate 1002 to provide a reduction in Miller effect and/or crosstalk. For example, a system may comprise a plurality of MOSFETs and each MOSFET (e.g., comprising MOSFET gate 1002) of the plurality of MOSFETs may be provided with cancelation current from an injection network circuit that is dedicated to the MOSFET. Accordingly, each of a plurality of injection network circuits (e.g., injection network circuit 1000) may operate independently and provide a specific cancelation current to a respectively corresponding MOSFET. In some embodiments, a system comprises two SiC MOSFETs that are arranged in a complementary phase-leg configuration, wherein a first SiC MOSFET is coupled to a first injection network circuit and a second SiC MOSFET is coupled to a second injection network circuit.

Accordingly, crosstalk voltage spikes of a SiC MOSFET may be significantly reduced by coupling an injection network circuit, such as injection network circuit 1000, to the SiC MOSFET. For example, positive voltage spike may be reduced by approximately 75% and negative voltage spike may be significantly reduced or completely removed. As such, the cancellation may reduce the chance of a false triggering and the potential for gate oxide breakdown. Miller plateaus may also be smoothed in both cases as compared to without using an injection network circuit. The injection network circuit 1000 may also prevent gate voltage of the SiC MOSFET from being held at a particular voltage level, and instead, may cause the SiC MOSFET to switch either fully on or off with little or no delay. An improvement of Miller plateaus may be further observed by the rising and falling times of V_{ds}. In particular, the reduction of the Miller plateau may lead to significant improvement in the switching speed of V_{ds}. The rising time of V_{ds} may be decreased by approximately 75% and the falling time may be decreased by approximately 25%. Thus, via coupling of a SiC MOSFET to an injection network circuit 1000, a substantial improvement in power efficiency may be provided given that a majority of power loss may be due to switching.

### CONCLUSION

It should be understood that the examples and embodiments described herein are for illustrative purposes only and that various modifications or changes in light thereof will be suggested to persons skilled in the art and are to be included within the spirit and purview of this application.

Many modifications and other embodiments of the present disclosure set forth herein will come to mind to one skilled in the art to which the present disclosures pertain having the benefit of the teachings presented in the foregoing descriptions and the associated drawings. Therefore, it is to be understood that the present disclosure is not to be limited to the specific embodiments disclosed and that modifications and other embodiments are intended to be included within the scope of the appended claim concepts. Although specific terms are employed herein, they are used in a generic and descriptive sense only and not for purposes of limitation.

What is claimed is:

1. A system comprising:
a current injection network that is coupled to a main circuit, the main circuit comprising a metal-oxide-semiconductor field-effect transistor (MOSFET), wherein the current injection network (i) is configured to provide a cancelation current to the MOSFET and (ii) comprises:
a gain stage subcircuit that is configured to (a) scale a drain-to-source voltage of the MOSFET, (b) provide an injection capacitor comprising a nonlinearity that matches a magnitude of a gate-to-drain capacitance current of the MOSFET, and (c) generate the cancelation current via the injection capacitor; and
an inversion stage subcircuit that is configured to invert a scaled drain-to-source voltage that is received from the gain stage subcircuit.

2. The system of claim 1, wherein the gain stage subcircuit comprises a nonlinear capacitance voltage divider circuit that includes a first gain stage diode, a second gain stage diode, a gain stage resistor, a first gain stage capacitor, and a second gain stage capacitor.

3. The system of claim 2, wherein the first gain stage diode and the second gain stage diode are reversely biased during a normal mode of operation.

4. The system of claim 2, wherein the second gain stage capacitor comprises an impedance that is significantly smaller than an impedance of the first gain stage capacitor and an impedance of a junction capacitance associated with the first gain stage diode.

5. The system of claim 4, wherein the gain stage resistor (i) comprises a resistance value that is significantly larger than the impedance of the second gain stage capacitor and (ii) is configured in parallel with the second gain stage capacitor to discharge the second gain stage capacitor upon disconnecting the gain stage subcircuit from the main circuit.

6. The system of claim 2, wherein the second gain stage diode is configured to clamp a negative output voltage.

7. The system of claim 2, wherein the second gain stage diode comprises a junction capacitance corresponding to an impedance that is significantly larger than an impedance of the second gain stage capacitor.

8. The system of claim 2, wherein the first gain stage diode comprises a reversely biased high voltage diode with a nonlinear junction capacitance that is voltage dependent and nonlinear.

9. The system of claim 2, wherein a voltage across the first gain stage diode and the first gain stage capacitor is approximately equal to the drain-to-source voltage.

10. The system of claim 1, wherein the inversion stage subcircuit comprises an N-MOSFET that is configured to an output of the gain stage subcircuit.

11. The system of claim 1, wherein the inversion stage subcircuit comprises an output that is coupled to the injection capacitor.

12. A system comprising:
a nonlinear voltage sensing network that is coupled to a metal-oxide-semiconductor field-effect transistor (MOSFET), wherein the nonlinear voltage sensing network is configured to generate an injection voltage;
an inverting linear amplifier that is configured to generate an inverted injection voltage from the injection voltage; and
an injection capacitor that is coupled to the inverting linear amplifier, wherein the injection capacitor is configured to provide a cancelation current to the MOSFET from the inverted injection voltage.
